(19) United States
(12) Patent Application Publication
(10) Pub. No.: US 2007/0090433 A1
(43) Pub. Date: Apr. 26, 2007

(54) Isolation collar void and methods of forming the same

(75) Inventors: Kangguo Cheng, Beacon, NY (US); Herbert L. Ho, New Windsor, NY (US); Jack A. Mandelman, Flat Rock, NC (US)

Correspondence Address: James R. Nock;IBM Corporation, Intellectual Property Law Dept. 917, 3605 Hwy. 52 North, Rochester, MN, 55901, US

(73) Assignee: International Business Machines Corporation, Armonk, NY (US)

(21) Appl. No.: 11/259,295

(22) Filed: Oct. 26, 2005

(51) Int. Cl. H01L 29/00; H01L 21/00

(52) U.S. Cl. 257/301; 257/532; 438/386; 438/243

(57) ABSTRACT

In a first aspect, a first apparatus is provided. The first apparatus includes a void formed around one or more portions of a microelectronic device in a bulk substrate. The void is adapted to reduce a parasitic leakage between the microelectronic device and the bulk substrate. Numerous other aspects are provided.

### FIELD OF THE INVENTION

The present invention relates generally to semiconductor device manufacturing, and more particularly to an isolation collar void and methods of forming the same during semiconductor device manufacturing.

### BACKGROUND OF THE INVENTION

Conventional methods of semiconductor device manufacturing may employ oxide to form an isolation collar around a semiconductor device being manufactured. However, the dielectric constant of oxide may require the isolation collar to have a minimum thickness to effectively provide isolation. An isolation collar of such thickness may not be practical for all types of semiconductor device manufacturing. Accordingly, improved isolation collars and methods of forming the same are desirable.

### SUMMARY OF THE INVENTION

In a first aspect of the invention, a first apparatus is provided. The first apparatus includes a void formed around one or more portions of a microelectronic device in a bulk substrate. The void is adapted to reduce a parasitic leakage between the microelectronic device and the bulk substrate.

In a second aspect of the invention, a second apparatus is provided. The second apparatus is a memory cell that includes (1) a microelectronic device formed in a bulk substrate; and (2) a void formed around one or more portions of the microelectronic device. The void is adapted to reduce a parasitic leakage between the microelectronic device and the bulk substrate.

In a third aspect of the invention, a first method is provided. The first method includes the steps of (1) providing a substrate including a microelectronic device; and (2) forming a void in the substrate around a portion of the microelectronic device. Numerous other aspects are provided in accordance with these and other aspects of the invention.

Other features and aspects of the present invention will become more fully apparent from the following detailed description, the appended claims and the accompanying drawings.

### BRIEF DESCRIPTION OF THE FIGURES

FIGS. 1A-B illustrate respective top and cross-sectional side views of a substrate following a step of a first exemplary method of forming an isolation collar void in which an oxide collar is formed in a trench of the substrate in accordance with an embodiment of the present invention.

FIGS. 2A-B illustrate respective top and cross-sectional side views of the substrate following a step of the first exemplary method of forming the isolation collar void in, which the trench is filled with conductive material in accordance with an embodiment of the present invention.

FIGS. 3A-C illustrate respective top, cross-sectional side and cross-sectional front views of the substrate following a step of the first exemplary method of forming the isolation collar void in which portions of the substrate are selectively removed in accordance with an embodiment of the present invention.

FIGS. 4A-C illustrate respective top, cross-sectional side and cross-sectional front views of the substrate following a step of the first exemplary method of forming the isolation collar void in which nitride spacers are formed on the substrate in accordance with an embodiment of the present invention.

FIGS. 5A-C illustrate respective top, cross-sectional side and cross-sectional front views of the substrate following a step of the first exemplary method of forming the isolation collar void in which oxide is removed from the substrate in accordance with an embodiment of the present invention.

FIGS. 6A-C illustrate respective top, cross-sectional side and cross-sectional front views of the substrate following a step of the first exemplary method of forming the isolation collar void in which nitride is removed from the substrate in accordance with an embodiment of the present invention.

FIGS. 7A-C illustrate respective top, cross-sectional side and cross-sectional front views of the substrate following a step of the first exemplary method of forming the isolation collar void in which oxide is deposited in an isolation trench of the substrate in accordance with an embodiment of the present invention.

FIGS. 8A-C illustrate respective top, cross-sectional side and cross-sectional front views of the substrate following a step of the first exemplary method of forming the isolation collar void in which nitride is deposited on the substrate in accordance with an embodiment of the present invention.

FIGS. 9A-C illustrate respective top, cross-sectional side and cross-sectional front views of the substrate following a step of the first exemplary method of forming the isolation collar void in which the isolation trench is filled with oxide in accordance with an embodiment of the present invention.

FIGS. 10A-C illustrate respective top, cross-sectional side and cross-sectional front views of the substrate following steps of a second exemplary method of forming the isolation collar void in which nitride and oxide are removed from the substrate and nitride spacers are formed on the substrate in accordance with an embodiment of the present invention.

FIGS. 11A-C illustrate respective top, cross-sectional side and cross-sectional front views of the substrate following a step of the second exemplary method of forming the isolation collar void in which silicon and trench conductive material may be removed from the substrate in accordance with an embodiment of the present invention.

FIGS. 12A-C illustrate respective top, cross-sectional side and cross-sectional front views of the substrate following a step of the second exemplary method of forming the isolation collar void in which oxide is removed from the substrate in accordance with an embodiment of the present invention.

FIGS. 13A-C illustrate respective top, cross-sectional side and cross-sectional front views of the substrate following a step of the second exemplary method of forming the isolation collar void in which oxide is deposited on the substrate in accordance with an embodiment of the present invention.

FIGS. 14A-C illustrate respective top, cross-sectional side and cross-sectional front views of the substrate following a step of the second exemplary method of forming the isolation collar void in which nitride is deposited on the substrate in accordance with an embodiment of the present invention.

FIGS. 15A-C illustrate respective top, cross-sectional side and cross-sectional front views of the substrate following a step of the second exemplary method of forming the isolation collar void in which oxide is deposited on the substrate in accordance with an embodiment of the present invention.

### DETAILED DESCRIPTION OF THE FIGURES

The present invention provides improved semiconductor devices and methods for making the same. More specifically, the present invention provides for fabrication of a capacitor isolation collar void around a deep trench storage capacitor that replaces the capacitor isolation collar oxide around a conventional deep trench storage capacitor. Use of a void decreases the dielectric constant (e.g., permittivity) and increases the dielectric strength of a capacitor isolation collar. Therefore, a thinner isolation collar may be employed. Consequently, deep trench storage capacitors with smaller geometries (e.g., 65 nm node) may be manufactured.

Further, in some embodiments, thin spacers (e.g., silicon nitride spacers) may be used to protect a pad oxide from undercut during void formation. Thus, conventional oxide isotropic etch methods may be employed to etch a capacitor isolation collar oxide when forming a capacitor isolation collar void.

A covering layer, such as an oxide layer, may be deposited over the capacitor isolation collar void to seal the opening (e.g., reentrant shape) left by the oxide isotropic etch. Covering the capacitor isolation collar void may prevent additional process steps from filling the capacitor isolation collar void. In at least one embodiment, the covering layer may be formed, for example, using a high density plasma (HDP) deposition with a small or no bias.

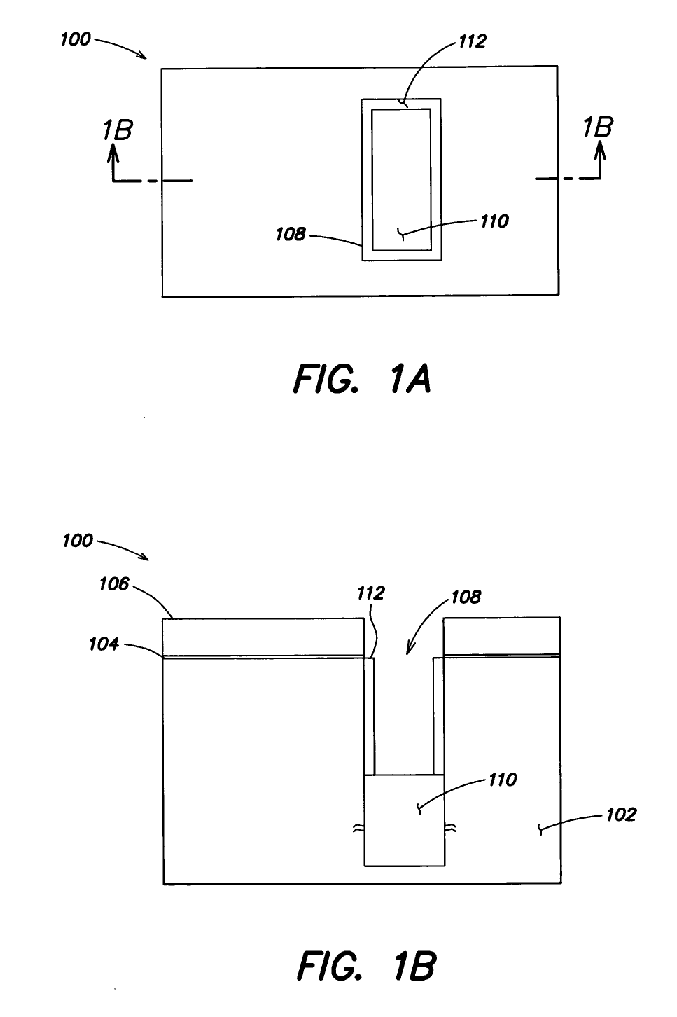

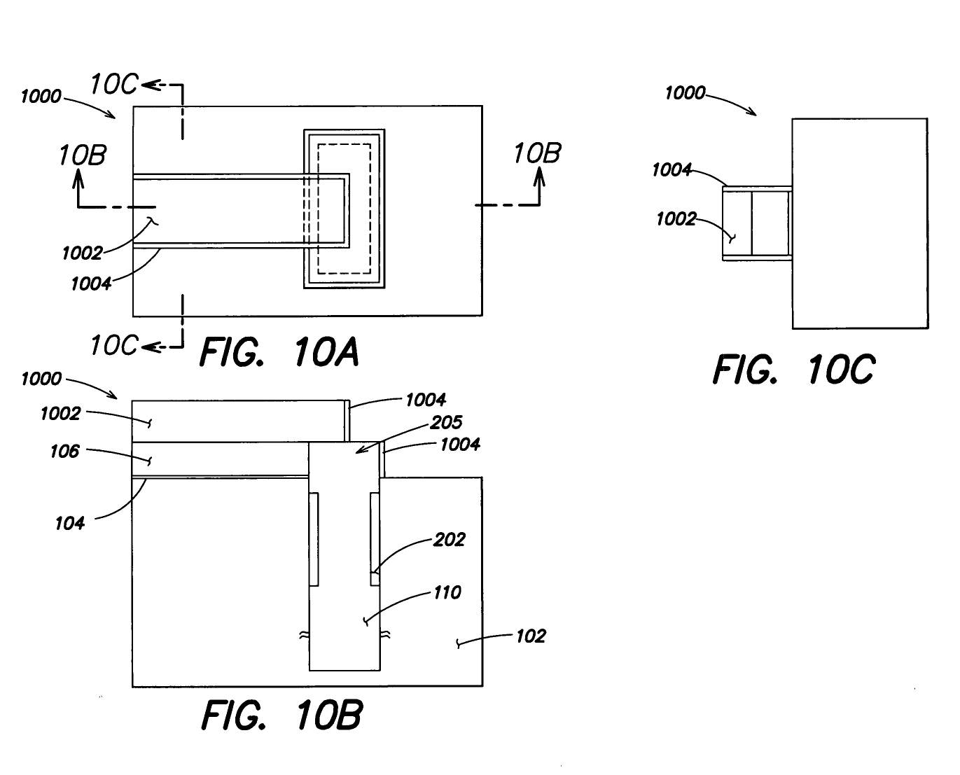

FIGS. 1A-9C illustrate views of a first exemplary method of forming an isolation collar void in accordance with an embodiment of the present invention. FIGS. 10A-15C illustrate views of a second exemplary method of forming an isolation collar void in accordance with an embodiment of the present invention. More specifically, FIGS. 1A-B illustrate respective top and cross-sectional side views of a substrate following a step of a first exemplary method of forming an isolation collar void in which an oxide collar is formed in a trench of the substrate 100 in accordance with an embodiment of the present invention. With reference to FIGS. 1A-B, a bulk substrate 102 is provided comprising silicon or other suitable material. A pad oxide layer 104 may be disposed on the upper surface of the bulk substrate 102. The pad oxide layer 104 may be about 1 nm to about 10 nm thick (although a larger or smaller and/or different thickness range may be employed). On the upper surface of the pad oxide layer 104, a pad nitride layer 106 may be deposited. The pad nitride layer 106 may be about 20 nm to about 500 nm thick (although a larger or smaller and/or different thickness range may be employed). Optionally, a layer of CVD oxide (not shown) may be formed over the pad nitride layer 106. The CVD oxide layer, which may serve as a hard mask during trench etching, may be about 100 nm to 1000 nm thick (although a larger or smaller and/or different thickness range may be employed). Using reactive ion etching (RIE) or another suitable method, a trench 108 may be formed in the pad nitride layer 106, the pad oxide layer 104 and the bulk substrate 102. The trench 108 may be about 22 nm to about 130 nm wide and about 2 μm to about 10 μm deep (although a larger or smaller and/or different width and/or depth range may be employed). A storage node conductor 110 may be formed in the lower region of the trench 108. The storage node conductor 110 may be about 1 μm to about 9 μm in vertical extent (although a larger or smaller and/or different vertical extent range may be employed). The storage node conductor 110 may occupy the entire width of the trench 108, and therefore, a thickness of the storage node conductor 110 may be based on the trench width. In addition, an oxide full collar 112 may be disposed in the trench 108 above the storage node conductor 110. The oxide full collar 112 may be about 15 nm to about 50 nm wide and/or about 0.75 μm to about 2.25 μm high (although a larger or smaller and/or different width and/or height range may be employed).

The pad oxide layer 104 and pad nitride layer 106 may be deposited on the bulk substrate 102 using processes such as chemical vapor deposition (CVD) or other suitable processes. The trench 108 may be formed so as to have a high aspect ratio and thus may be referred to as a deep trench in the art (as illustrated above). In the lower region of the trench 108 the storage node conductor 110 and the oxide full collar 112 may be deposited using CVD or another suitable method followed by RIE or another suitable method.

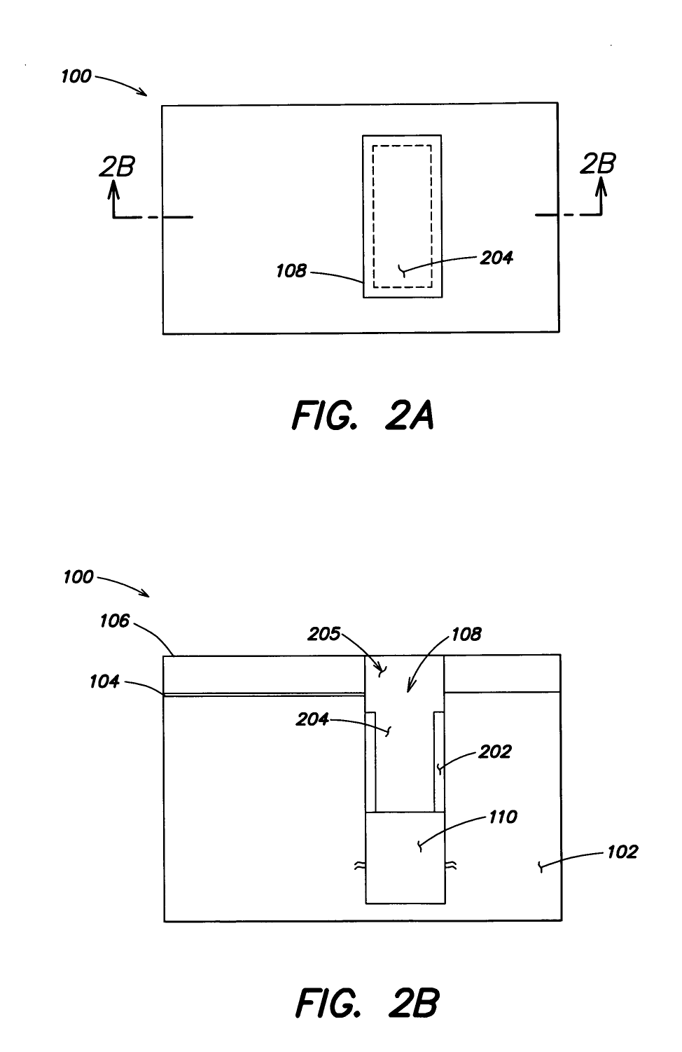

FIGS. 2A-B illustrate respective top and cross-sectional side views of a substrate following a step of the first exemplary method of forming the isolation collar void in which the trench 108 is filled with conductive material in accordance with an embodiment of the present invention. With reference to FIGS. 2A-B, an oxide part collar 202 may be formed by removing an upper portion of the oxide full collar (112 in FIGS. 1A-B) so as to expose a portion of the sidewalls of the trench 108. The oxide part collar 202 may be about 0.25 μm to about 2.0 m high (although a larger or smaller and/or different height range may be employed). A layer of conductive material 204 may be formed in the trench 108. The layer of conductive material 204 may fill the remaining unfilled portions of the trench 108. The upper surface of the layer of conductive material 204 may be approximately planar with the upper surface of the pad nitride layer 106. The lower surface of the layer of conductive material 204 may be approximately coplanar with the upper surface of the storage node conductor 110. The conductive material may be N+ doped polysilicon or another suitable material. In this manner, an upper portion of the conductive material layer 204 (e.g., a portion adjacent an upper horizontal surface of the part collar 202) may serve as or be formed into a buried strap outdiffusion region 205 (e.g., buried strap).

More specifically, to form the oxide part collar, an upper portion of the oxide full collar (112 in FIGS. 1A-B) may be removed using an isotropic etch which is masked by a recessed trench fill or another suitable method. Further, the layer of conductive material 204 may be formed by using CVD or another suitable method. The layer of conductive material 204 may include N+ doped (e.g., heavily doped) polycrystalline silicon (although other suitable materials may be employed). The layer of conductive material 204 may be planarized with the top surface of the pad nitride using CMP or another suitable method.

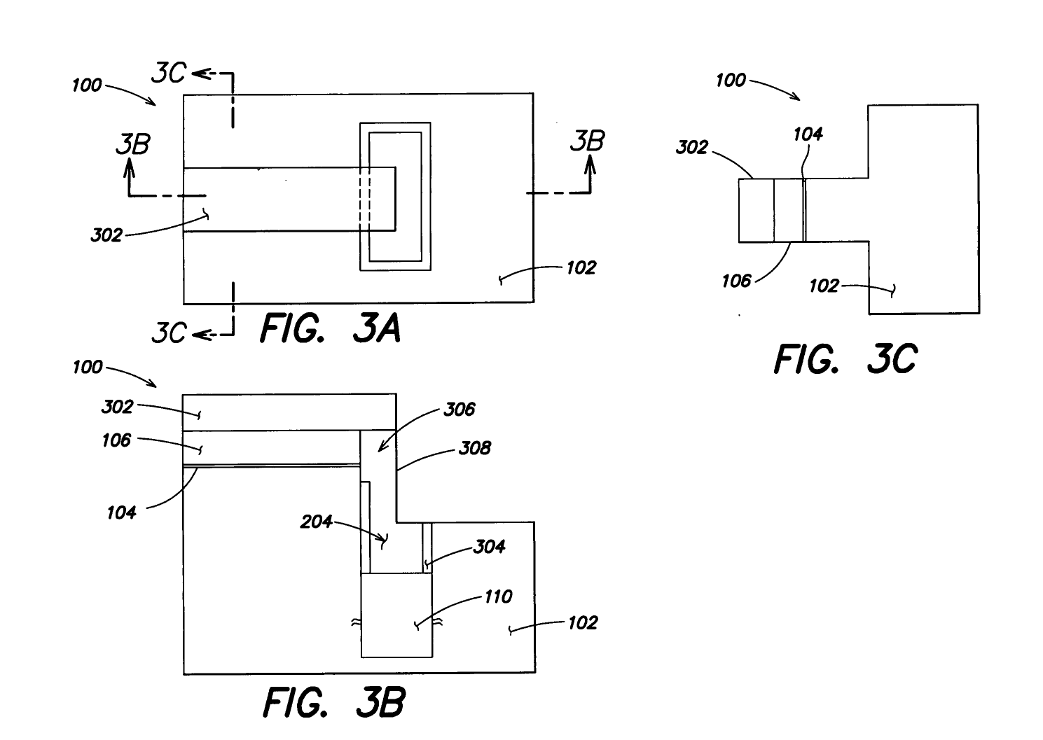

FIGS. 3A-C illustrate respective top, cross-sectional side and cross-sectional front views of a step of the first exemplary method of forming the isolation collar void in which portions of the substrate 100 are selectively removed in accordance with an embodiment of the present invention. With reference to FIG. 3A-C, a mask such as an oxide hard mask 302 may be formed on the substrate 100. More specifically, the oxide hard mask 302 may be formed on a portion of the pad nitride layer 106 and a portion of the top of the buried strap 205. The mask 302 may be about 100 nm to about 1000 nm thick (although a larger or smaller and/or different thickness range may be employed). The oxide hard mask 302 may be formed using CVD or another suitable method followed by RIE or another suitable method. Although an oxide hard mask 302 is described above, the hard mask 302 may be formed of different and/or additional materials.

The oxide hard mask 302 is patterned and the portion of the substrate 100 not covered by the oxide hard mask 302 may be exposed to subsequent processes. The mask 302 may be positioned such that about one third to about one half of the width of the trench 108 may be exposed to the subsequent processing (although the mask 302 may expose a larger or smaller portion of the buried strap 205). These processes may remove portions of the pad nitride layer 106, the pad oxide layer 104, the oxide hard mask 302, the oxide part collar (202 in FIGS. 2A-B), the layer of conductive material 204, buried strap 205 and/or the bulk substrate 102 so as to form an isolation oxide collar 304 and a resulting buried strap 306. The processes used to form the isolation oxide collar 304 and the resulting buried strap 306 may be RIE or other suitable processes. In this manner, an isolation trench 308 may be formed comprising an approximately vertical surface on the resulting buried strap 306. The isolation trench 308 may also comprise an approximately horizontal surface that includes a portion of the isolation oxide collar 304, a portion of the resulting buried strap 306 and a portion of the bulk substrate 102. In this manner, a portion of the isolation oxide collar 304 may be exposed. The isolation trench 308 may be about 22 nm to about 500 nm wide and about 0.20 μm to about 1.5 μm deep (although a larger or smaller and/or different width and/or depth range may be employed).

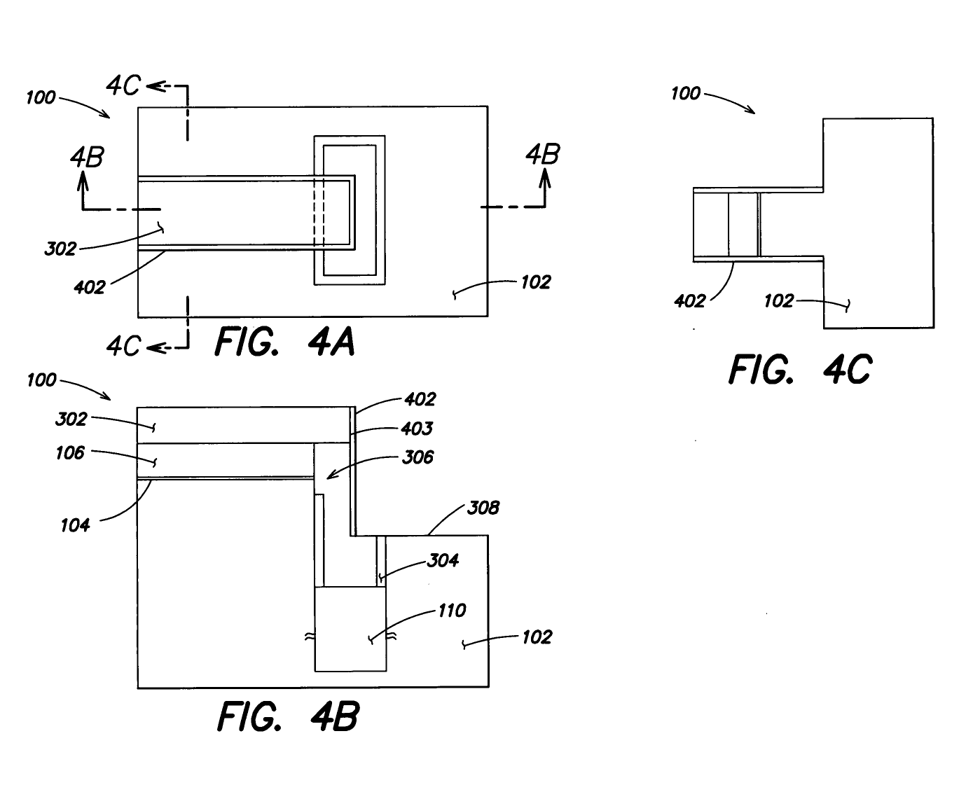

FIGS. 4A-C illustrate respective top, cross-sectional side and cross-sectional front views of a step of the first exemplary method of forming the isolation collar void in which nitride spacers are formed on the substrate 100 in accordance with an embodiment of the present invention. With reference to FIG. 4A-C, a nitride spacer 402 may be disposed on a side wall 403 of the trench 308. The nitride spacer 402 may be formed by depositing a conformal nitride (e.g., silicon nitride) layer or another suitable material layer over a portion of the bulk substrate 102, isolation oxide collar 304, resulting buried strap 306 and oxide hard mask 302, and directionally etching such layer. However, other suitable methods may be employed to form the nitride spacer 402. The nitride spacer 402 may be about 1 nm to about 30 nm thick (although a larger or smaller and/or different thickness range may be employed).

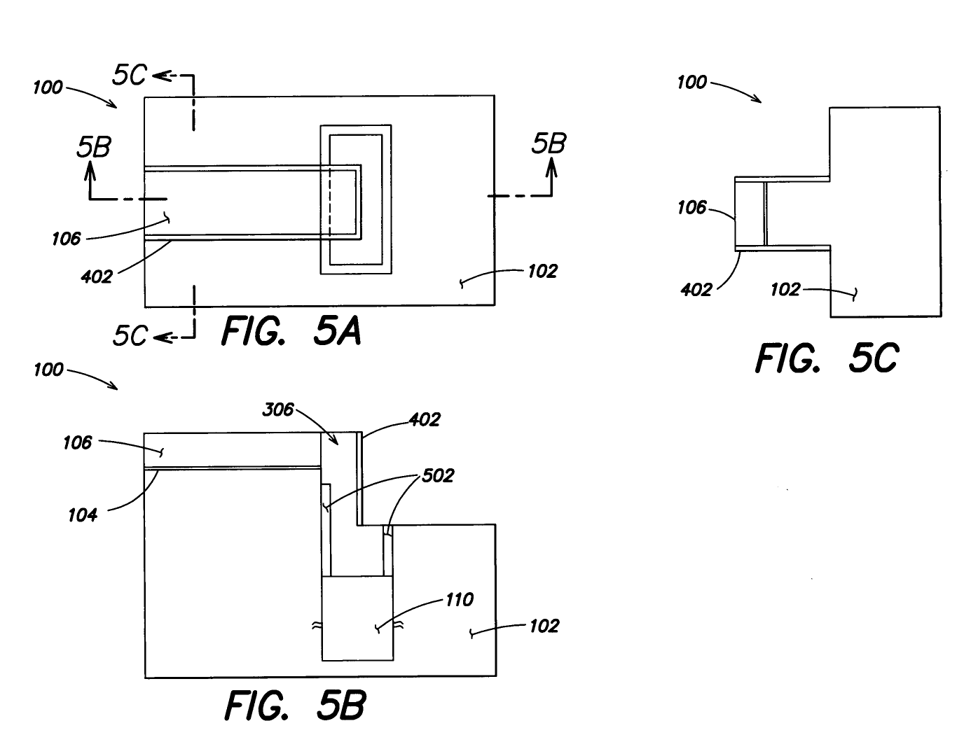

FIGS. 5A-C illustrate respective top, cross-sectional side and cross-sectional front views of the substrate 100 following a step of the first exemplary method of forming the isolation collar void in which oxide is removed from the substrate in accordance with an embodiment of the present invention. With reference to FIGS. 5A-C, the horizontal portion of the resulting buried strap 306, a portion of the isolation oxide collar (304 in FIGS. 4A-C), the oxide hard mask (302 in FIGS. 4A-C) and a portion of the bulk substrate 102 may be exposed to a selective material removal process. The selective material removal process may include an isotropic oxide etch (e.g., a wet or dry etch) and/or other suitable methods. In this manner, a substantial portion of isolation collar oxide and the oxide hard mask 302 may be removed so as to form an isolation collar void 502 and expose a portion of the pad nitride 106. In this manner, the isolation collar void 502 may be formed around the resulting buried strap 306. Note that a portion of the isolation collar void 502 may be exposed to process gases.

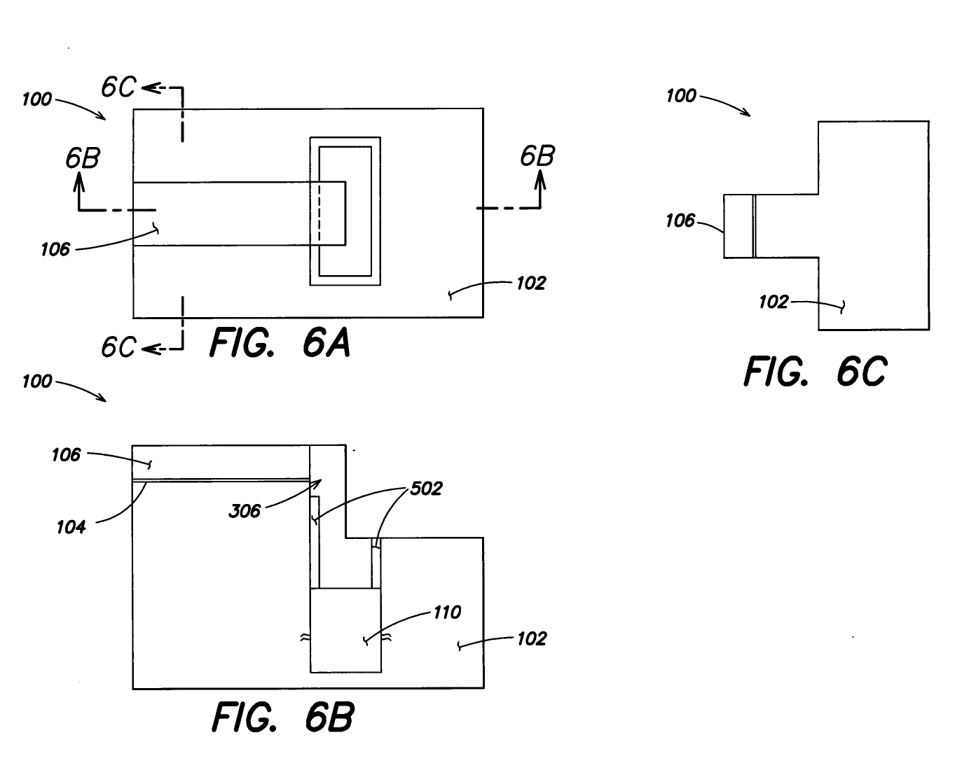

FIGS. 6A-C illustrate respective top, cross-sectional side and cross-sectional front views of the substrate following a step of the first exemplary method of forming the isolation collar void in which nitride is removed from the substrate in accordance with an embodiment of the present invention. With reference to FIGS. 6A-C, the nitride spacer 402 may be exposed to a selective material removal process so as to remove the nitride spacer 402. The selective material removal process may include a process such as a strip process or other suitable method. By employing this process a small portion of the pad nitride layer 106 may be removed.

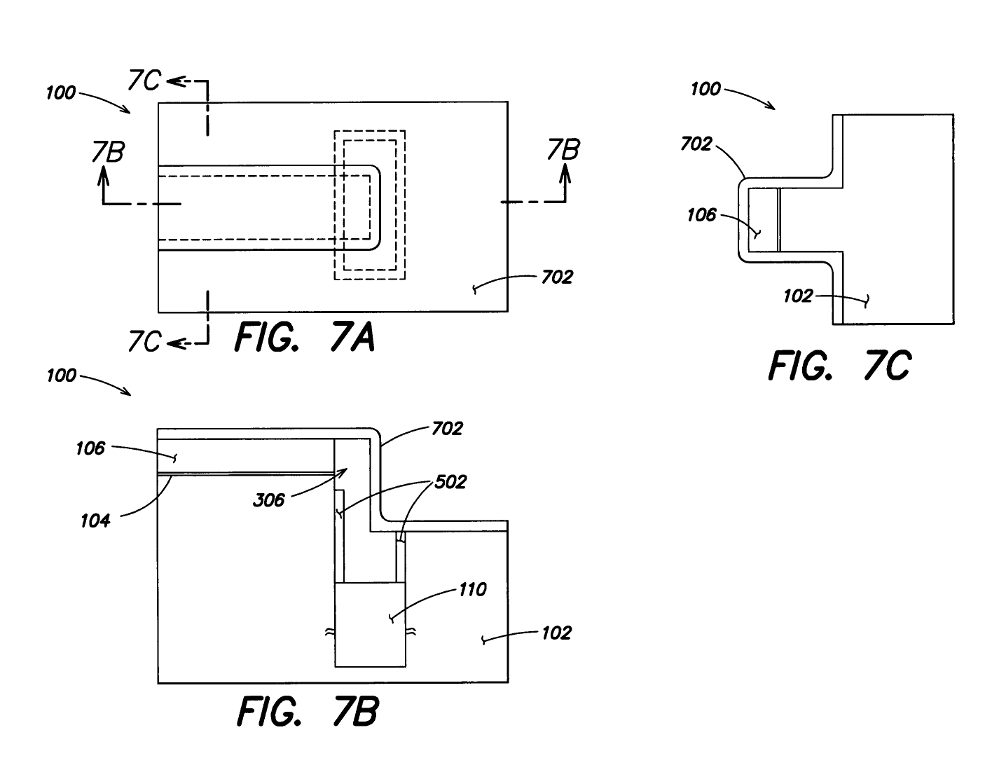

FIGS. 7A-C illustrate respective top, cross-sectional side and cross-sectional front views of the substrate 100 following a step of the first exemplary method of forming the isolation collar void in which oxide is deposited in an isolation trench of the substrate in accordance with an embodiment of the present invention. With reference to FIGS. 7A-C, an oxide covering layer 702 may be formed. For example, a layer of oxide or other suitable material may be deposited conformably by an unbiased HDP deposition at temperatures of about 300 C to 400 C so as to form the oxide covering layer 702 (although a larger or smaller and/or different temperature range may be employed). The low temperature deposition may inhibit migration of adsorbed reactants over the surface and may promote the formation of the oxide covering layer 702 at the edges of surfaces. However, other suitable methods may be employed to form the oxide covering layer 702. This reentrant shape may plug openings to the isolation void collar 502. The oxide covering layer 702 may be about 10 nm to about 60 nm thick (although a larger or smaller and/or different thickness range may be employed).

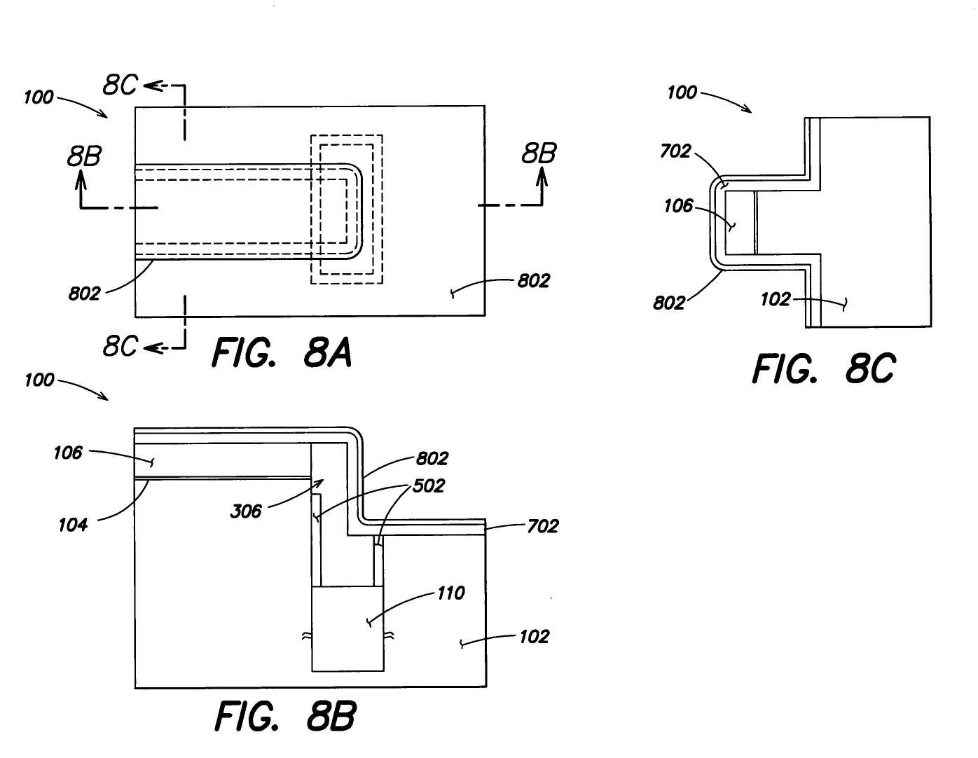

FIGS. 8A-C illustrate respective top, cross-sectional side and cross-sectional front views of the substrate 100 following a step of the first exemplary method of forming the isolation collar void in which nitride is deposited on the substrate in accordance with an embodiment of the present invention. With reference to FIGS. 8A-C, the conformably deposited void covering layer 702 may be covered with a silicon nitride layer 802. The silicon nitride layer made be deposited using CVD or other suitable processes. The silicon nitride layer 802 may be about 2 nm to about 20 nm thick (although a larger or smaller and/or different thickness range may be employed).

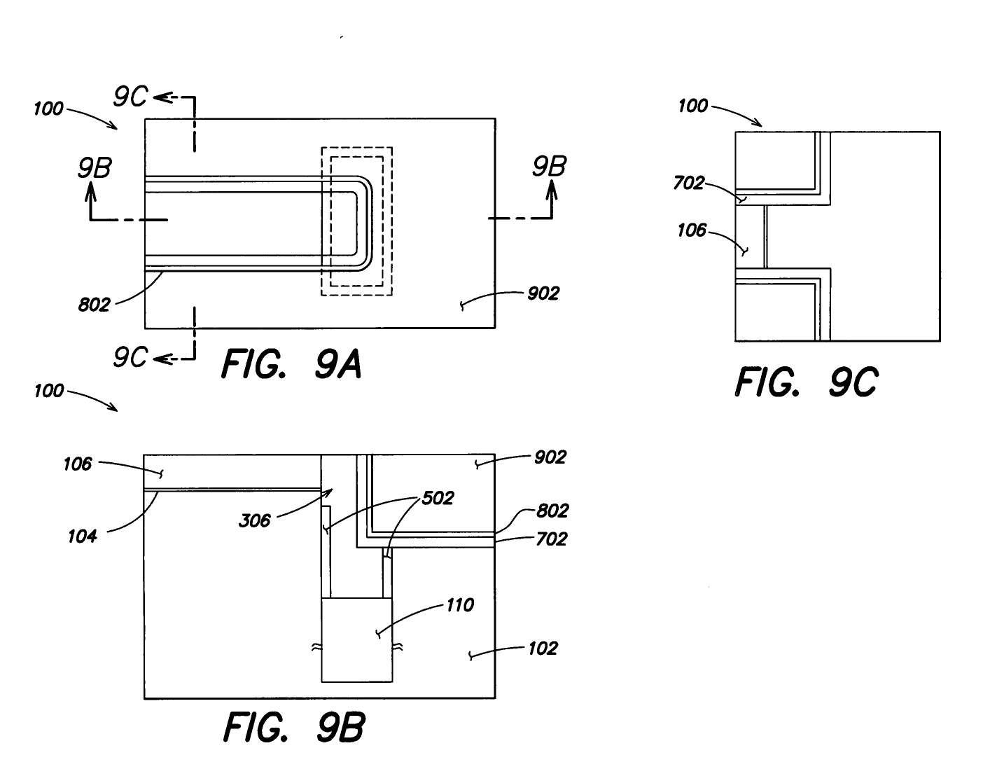

FIGS. 9A-C illustrate respective top, cross-sectional side and cross-sectional front views of the substrate following a step of the first exemplary method of forming the isolation collar void in which the isolation trench is filled with oxide in accordance with an embodiment of the present invention. With reference to FIGS. 9A-C, the isolation trench 308 may be filled with an oxide material so as to form a trench fill 902 although other suitable materials may be used. The fill process may be done with HDP oxide although other suitable processes may be employed. Subsequent to forming the trench fill 902, the top surface of the trench fill 902 may be planarized using chemical mechanical planarization (CMP) or other suitable methods.

FIGS. 10A-C illustrate respective top, cross-sectional side and cross-sectional front views of a substrate 1000 following steps of a second exemplary method of forming the isolation collar void in which nitride and oxide are removed from the substrate and nitride spacers are formed on the substrate in accordance with an embodiment of the present invention. Such steps of the second exemplary method are similar to the steps described with reference to FIGS 1A-3C. The substrate 1000 may be similar to the substrate 100 employed during the first exemplary method. When convenient, the same numerals are employed to refer to components of the substrate 1000 corresponding to the substrate 100. With reference to FIGS. 10A-C, a selective directional removal process may be employed to remove a portion of the bulk substrate 102. In this manner, an approximately vertical and an approximately horizontal surface may be exposed on the buried strap 205. More specifically, an oxide hard mask 1002 may be formed on the top layer of the pad nitride layer 106 and a portion of the top of the buried strap 205 (e.g., round buried strap) by employing a material deposition process such as chemical vapor deposition (CVD) or another suitable method followed by RIE or another suitable method. The oxide hard mask 1002 may be employed to remove portions of the pad nitride layer 106 and/or pad oxide layer 104.

Subsequent to the formation of the oxide hard mask 1002, a portion of the bulk substrate 102, the oxide part collar 202, buried strap 205 and the part oxide hard mask 1002 may be conformably covered with a layer of silicon nitride or another suitable material. The process that may be employed to form the silicon nitride layer or another suitable material may include CVD or another suitable method. The silicon nitride layer or other suitable material may be exposed to a directional material removal process such as RIE or another suitable method so as to form the approximately vertical silicon nitride spacers 1004. The nitride spacers 1004 may be about 1 nm to about 30 nm thick (although a larger or smaller and/or different thickness range may be employed).

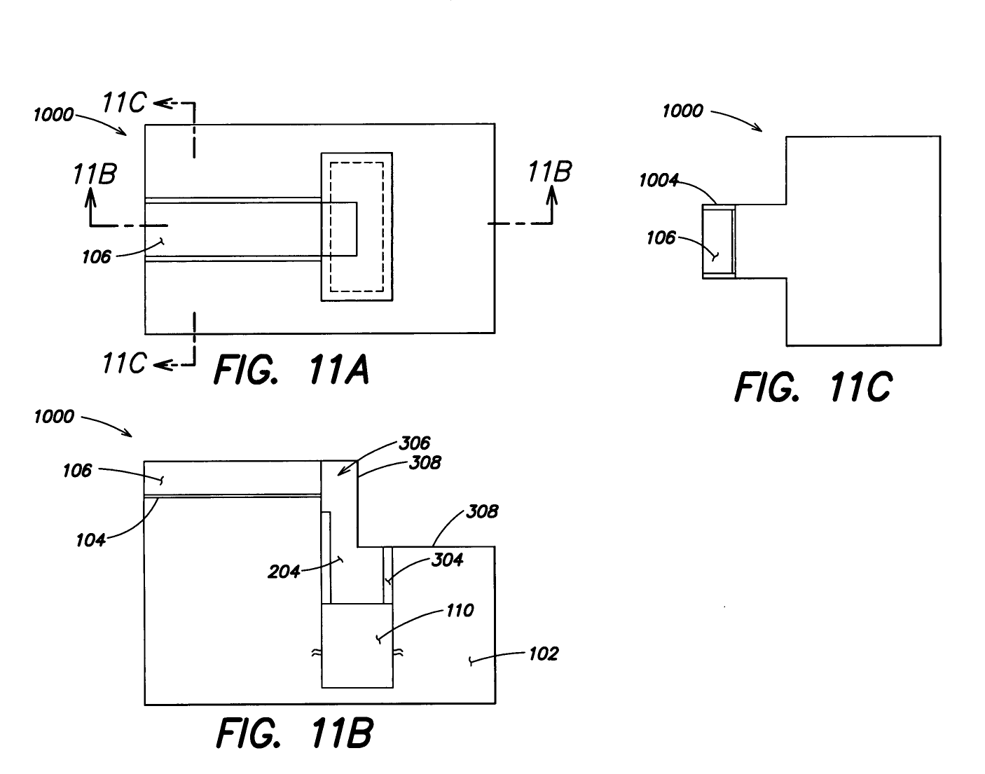

FIGS. 11A-C illustrate respective top, cross-sectional side and cross-sectional front views of the substrate 1000 following a step of the second exemplary method of forming the isolation collar void in which silicon and trench conductive material may be removed from the substrate in accordance with an embodiment of the present invention. With reference to FIGS. 11A-C, the oxide hard mask (1002 in FIGS. 10A-C), pad nitride layer 106, conductive material layer 204, buried strap (205 in FIGS. 10A-C), bulk substrate 102 may be exposed to a directional material removal process. The directional material removal process may include processes such as a RIE process or other suitable methods. The directional material removal process may selectively remove a portion of the layer of conductive material 204, buried strap 205, the pad nitride layer 106, the oxide part collar (202 in FIGS. 10A-C) and the bulk substrate 102. The RIE may remove the oxide hard mask (1002 in FIGS. 10A-C). In this manner, an isolation trench 308 may be formed comprising an approximately vertical surface of a resulting buried strap 306. The trench 308 may also comprise an approximately horizontal surface that may be comprised of a portion of the isolation oxide collar 304, the resulting buried strap 306 and a portion of the bulk substrate 102. In this manner, a portion of the isolation oxide collar 304 may be exposed. The isolation trench 308 may be about 22 nm to about 500 nm wide and about 0.2 μm to about 1.5 μm deep (although a larger or smaller and/or different width and/or depth range may be employed).

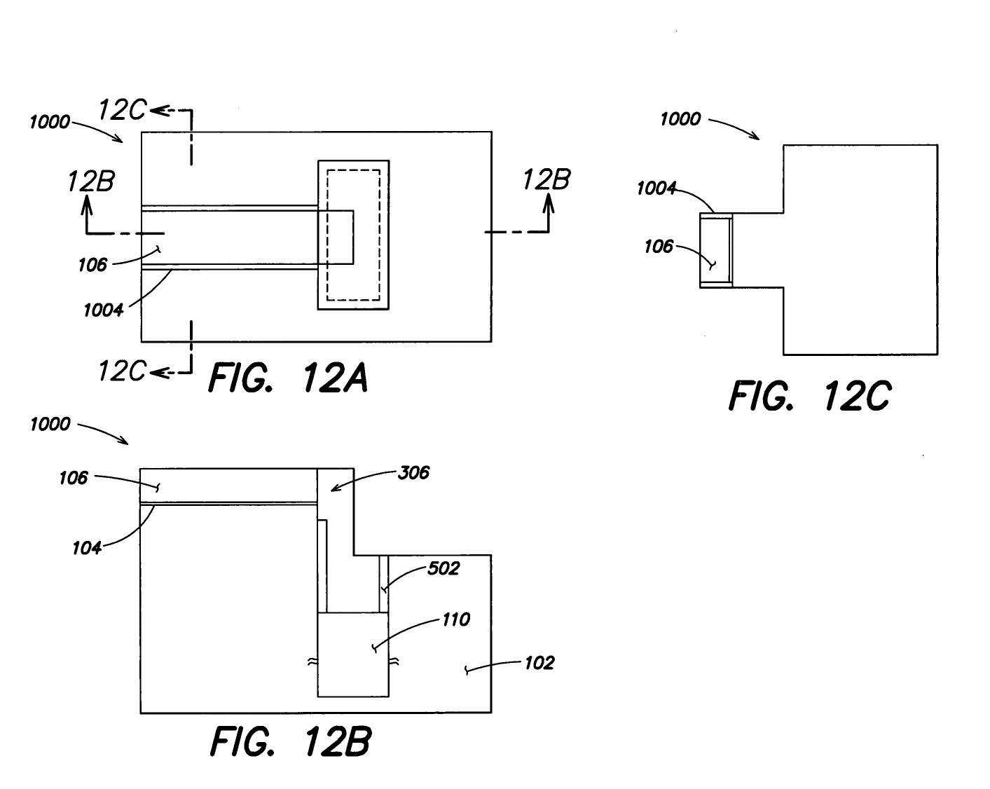

FIGS. 12A-C illustrate respective top, cross-sectional side and cross-sectional front views of the substrate 1000 following a step of the second exemplary method of forming the isolation collar void in which oxide is removed from the substrate in accordance with an embodiment of the present invention. This step is similar to the step of the first exemplary method described with reference to FIGS. 6A-C, and therefore, is not described in detail herein. However, the pad oxide layer 104 may be protected by the nitride spacer 1004 while oxide is etched from the substrate 1000.

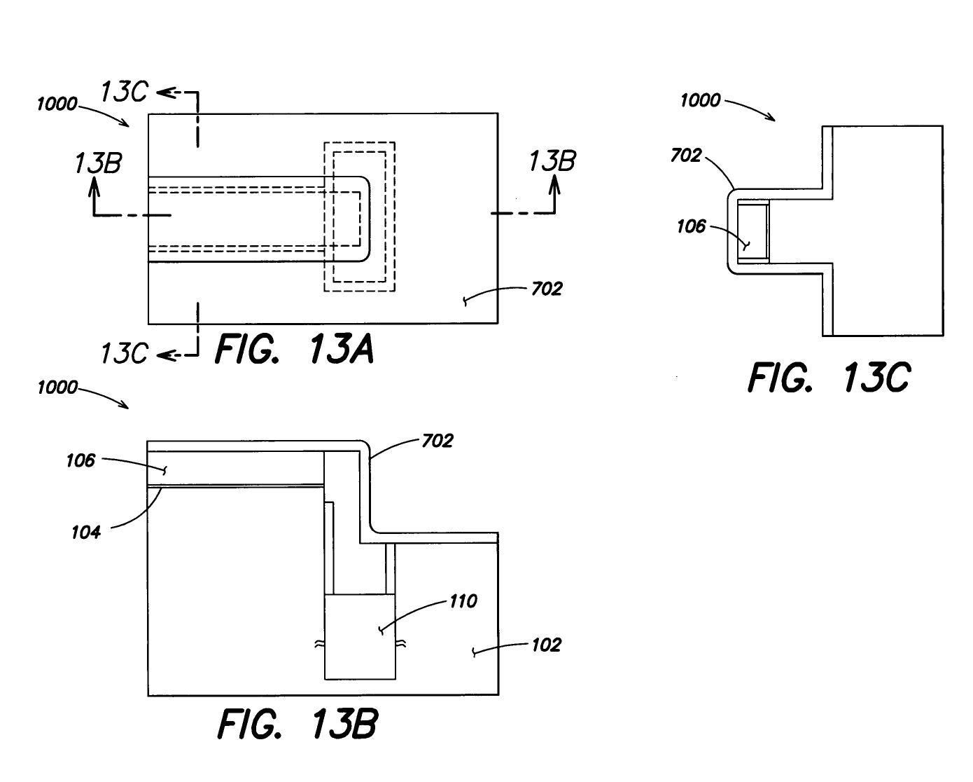

FIGS. 13A-C illustrate respective top, cross-sectional side and cross-sectional front views of the substrate 1000 following a step of the second exemplary method of forming the isolation collar void in which oxide is deposited on the substrate in accordance with an embodiment of the present invention. This step is similar to the step of the first exemplary method described with reference to FIGS. 7A-C, and therefore, is not described in detail herein.

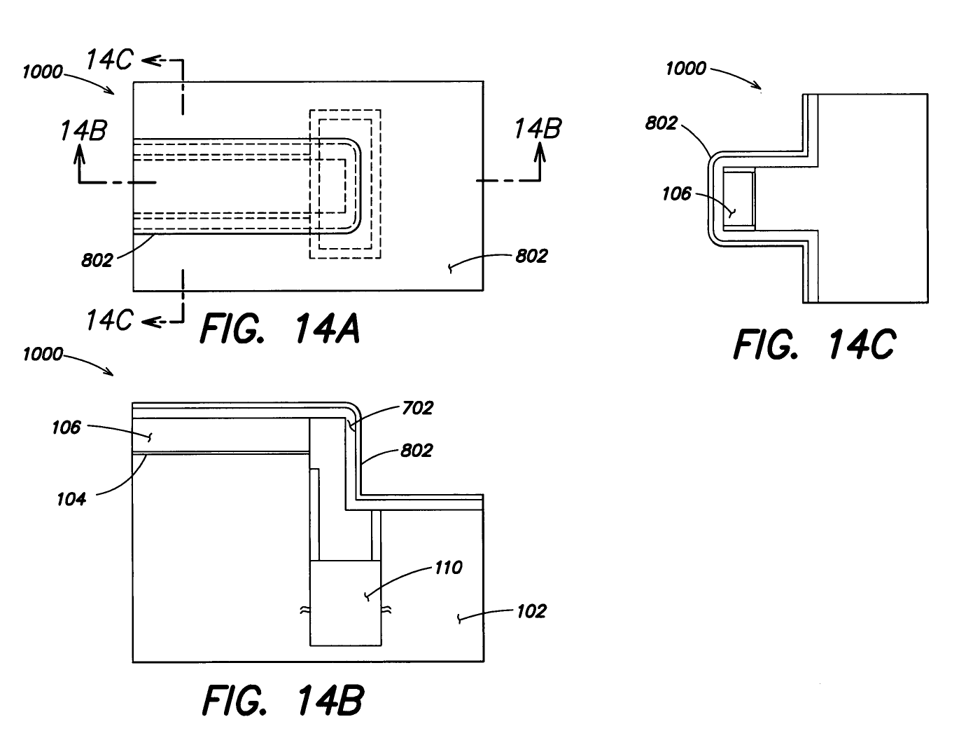

FIGS. 14A-C illustrate respective top, cross-sectional side and cross-sectional front views of the substrate 1000 following a step of the second exemplary method of forming the isolation collar void in which nitride is deposited on the substrate in accordance with an embodiment of the present invention. This step is similar to the step of the first exemplary method described with reference to FIGS. 8A-C, and therefore, is not described in detail herein.

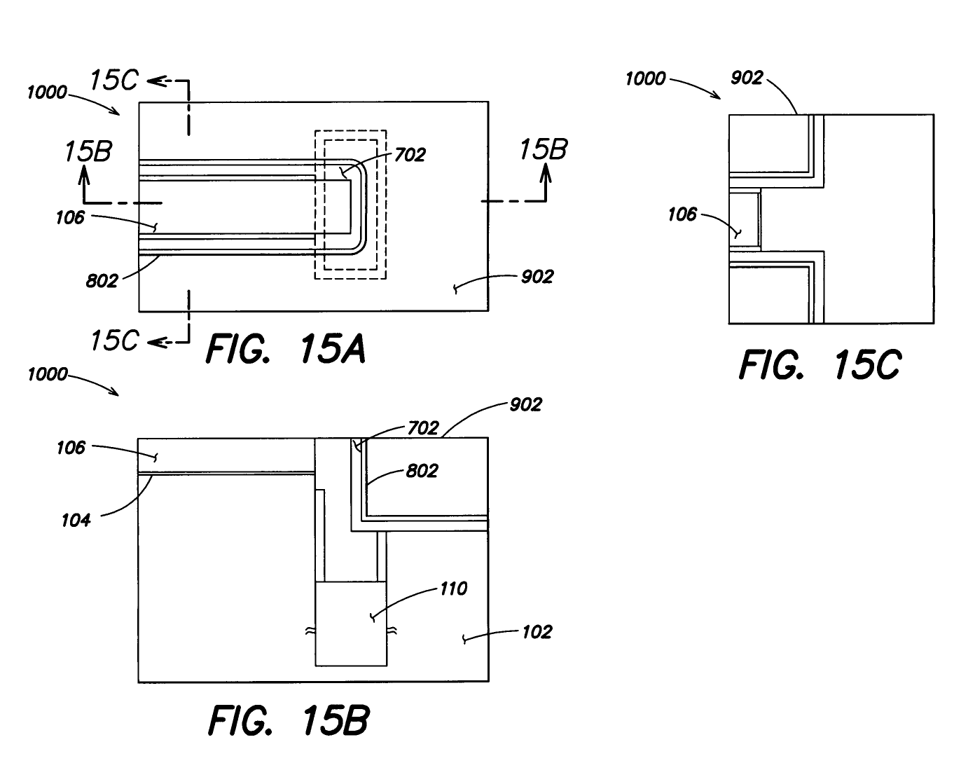

FIGS. 15A-C illustrate respective top, cross-sectional side and cross-sectional front views of the substrate following a step of the second exemplary method of forming the isolation collar void in which oxide is deposited on the substrate in accordance with an embodiment of the present invention. This step is similar to the step of the first exemplary method described with reference to FIGS. 9A-C, and therefore, is not described in detail herein.

The foregoing description discloses only exemplary embodiments of the invention. Modifications of the above disclosed apparatus and method which fall within the scope of the invention will be readily apparent to those of ordinary skill in the art. For instance, although an isolation collar void is described above, in some embodiments, the isolation collar may be formed from a material having a dielectric constant similar to the void (e.g., approximately 1). For example, the isolation collar void may be filled with the material having such dielectric constant.

Accordingly, while the present invention has been disclosed in connection with exemplary embodiments thereof, it should be understood that other embodiments may fall within the spirit and scope of the invention, as defined by the following claims.

The invention claimed is:

1. An apparatus, comprising:
a void formed around one or more portions of a microelectronic device in a bulk substrate;
wherein the void is adapted to reduce a parasitic leakage between the microelectronic device and the bulk substrate.

2. The apparatus of claim 1, wherein the void is defined by a sidewall of a portion of the microelectronic device and a sidewall of the bulk substrate.

3. The apparatus of claim 1, where in the void includes a vacuum.

4. The apparatus of claim 1, wherein the void comprises at least one gas.

5. The apparatus of claim 1, wherein the void is covered by a void covering layer adapted to prevent the entry of a substance into the void.

6. The apparatus of claim 2, wherein the void is defined by an approximately vertical sidewall of the microelectronic device and the approximately vertical sidewall of the bulk substrate.

7. The apparatus of claim 2, wherein the void is formed by removing oxide adjacent the sidewall of the portion of the microelectronic device and the sidewall of the bulk substrate.

8. A memory cell, comprising:
a microelectronic device formed in a bulk substrate; and
a void formed around one or more portions of the microelectronic device;
wherein the void is adapted to reduce a parasitic leakage between the microelectronic device and the bulk substrate.

9. The memory cell of claim 8, wherein the void is defined by a sidewall of a portion of the microelectronic device and a sidewall of the bulk substrate.

10. The memory cell of claim 8, wherein in the void includes a vacuum.

11. The memory cell of claim 8, wherein the void comprises at least one gas.

12. The memory cell of claim 8, wherein the void is covered by a void covering layer adapted to prevent the entry of a substance into the void.

13. The memory cell of claim 9, wherein the void is defined by an approximately vertical sidewall of the microelectronic device and the approximately vertical sidewall of the bulk substrate.

14. The memory cell of claim 9, wherein the void is formed by removing the oxide spacer from the sidewall of the portion of the microelectronic device and the sidewall of the bulk substrate.

15. A method, comprising;
(a) providing a substrate including a microelectronic device; and
(b) forming a void in the substrate around a portion of the microelectronic device.

16. The method of claim 15, further comprising forming a void covering layer adapted to prevent entry of a substance into the void over the void.

17. The method of claim 16 wherein forming the void covering layer includes depositing an oxide layer on the substrate

18. The method of claim 17 wherein depositing the oxide layer on the substrate includes employing a high density plasma deposition at about 300 C. to about 400 C. to deposit the oxide layer.

19. The method of claim 15 wherein (b) includes removing oxide around the portion of the microelectronic device.

20. The method of claim 15 wherein (b) includes forming a nitride spacer along a sidewall of a pad oxide layer.
